(19) United States
(12) Patent Application Publication
(10) Pub. No.: US 2026/0262459 A1
(43) Pub. Date: Sep. 3, 2026

(54) PROCESSING METHOD, METHOD OF MANUFACTURING SEMICONDUCTOR DEVICE, PROCESSING APPARATUS, AND RECORDING MEDIUM

(71) Applicant: KOKUSAI ELECTRIC CORPORATION, Tokyo (JP)

(72) Inventors: Motomu DEGAI, Toyama (JP); Eitetsu KATAGIRI, Toyama (JP); Takayuki WASEDA, Toyama (JP); Shoma MIYATA, Toyama (JP); Kimihiko NAKATANI, Toyama (JP)

(73) Assignee: KOKUSAI ELECTRIC CORPORATION, Tokyo (JP)

(21) Appl. No.: 19/657,147

(22) Filed: Apr. 24, 2026

Related U.S. Application Data
(63) Continuation of application No. PCT/JP2024/010285, filed on Mar. 15, 2024.

(51) Int. Cl. H10P 50/00; H10P 50/28; H10P 50/68; H10P 72/00

(52) U.S. Cl. CPC H10P 50/73; H10P 50/283; H10P 50/683; H10P 72/0421; H10P 72/0424

(57) ABSTRACT

Included is (a) modifying a surface of a first material by exposing a substrate, the surface of which includes the first material and a second material containing the same element as an element contained in the first material, to the modifying agent; and (b) etching the second material by exposing the substrate, in which the surface of the first material has been modified, to an etching agent.

### CROSS-REFERENCE TO RELATED APPLICATION

This application is a Bypass Continuation Application of PCT International Application No. PCT/JP2024/010285, filed on Mar. 15, 2024, the entire contents of which are incorporated herein by reference.

### BACKGROUND

### Field

The present disclosure relates to a processing method, a method of manufacturing a semiconductor device, a processing apparatus, and a recording medium.

### Description of the Related Art

As one of steps of manufacturing a semiconductor device, processing of removing a material exposed to a surface of a substrate by etching is performed in some cases (for example, refer to Japanese Patent Application Laid-Open No. 2021-082774 and Japanese Patent Application Laid-Open No. 2022-018973).

### SUMMARY

### Technical Problem

The present disclosure provides a technique that can perform selective etching with high accuracy.

### Solution to Problem

According to one embodiment of the present disclosure, there is provided a technique that includes: (a) modifying a surface of a first material by exposing a substrate, the surface of which includes the first material and a second material containing the same element as an element contained in the first material, to the modifying agent such that at least a part X of a molecular structure of a molecule contained in a modifying agent adsorbs to the surface of the first material to form a first inhibitor layer; and (b) etching the second material by exposing the substrate, in which the surface of the first material has been modified, to an etching agent.

### BRIEF DESCRIPTION OF THE DRAWINGS

FIG. 1 is a schematic configuration diagram of a vertical processing furnace of a processing apparatus suitably used in one embodiment of the present disclosure, illustrating a longitudinal cross-sectional view of a processing furnace 202 portion.

FIG. 2 is a schematic configuration diagram of the vertical processing furnace in the processing apparatus suitably used in one embodiment of the present disclosure, illustrating a cross-sectional view of the processing furnace 202 portion taken along line A-A of FIG. 1.

FIG. 3 is a schematic configuration diagram of a controller 121 of the processing apparatus suitably used in one embodiment of the present disclosure, illustrating a control system of the controller 121 in a block diagram.

FIG. 4A is a partially enlarged cross-sectional view illustrating a surface portion of a substrate in one embodiment of the present disclosure including a first material and a second material on a surface. FIG. 4B is a partially enlarged cross-sectional view illustrating the surface portion of the substrate in one embodiment of the present disclosure after being exposed to a modifying agent from a state of FIG. 4A. FIG. 4C is a partially enlarged cross-sectional view illustrating the surface portion of the substrate in one embodiment of the present disclosure after the second material is removed by exposure to an etching agent from a state of FIG. 4B. FIG. 4D is a partially enlarged cross-sectional view illustrating the surface portion of the substrate in one embodiment of the present disclosure after being exposed to the removing agent from a state of FIG. 4C.

### DETAILED DESCRIPTION

### <One Embodiment of Present Disclosure>

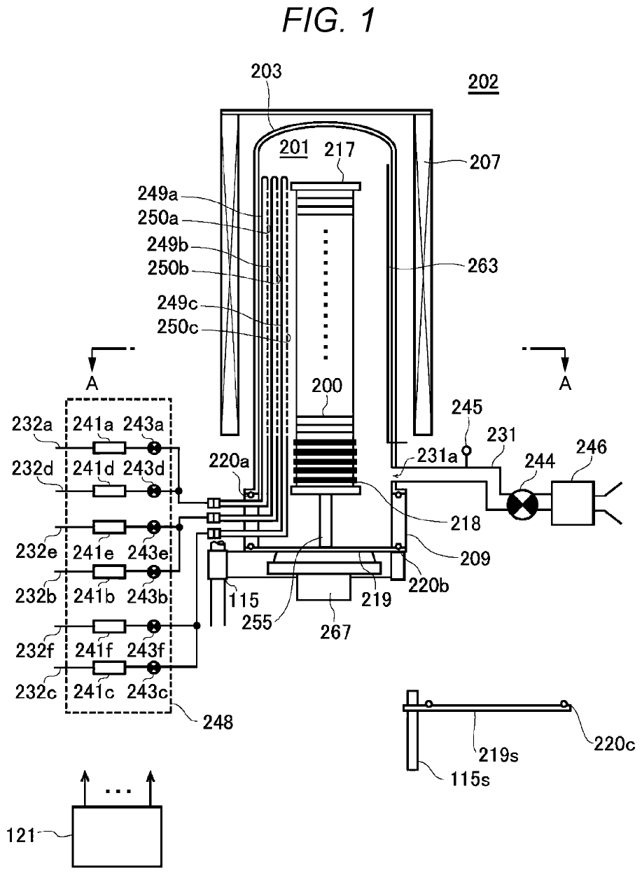

One embodiment of the present disclosure will be hereinafter described mainly with reference to FIGS. 1 to 3, and FIGS. 4A to 4D. The drawings used in the following description are all schematic, and dimensional relationships of respective elements, ratios of respective elements and the like illustrated in the drawings do not necessarily coincide with actual ones. Dimensional relationships between elements, ratios between elements and the like do not necessarily coincide between a plurality of drawings, too.

### (1) Configuration of Processing Apparatus

As illustrated in FIG. 1, a processing furnace 202 of a processing apparatus includes a heater 207 serving as a temperature regulator (heater). The heater 207 has a cylindrical shape and is supported by a holding plate to be vertically installed. The heater 207 also functions as an activator (exciter) that thermally activates (excites) a gas.

Inside the heater 207, a reaction tube 203 is disposed concentrically with the heater 207. The reaction tube 203 is made of, for example, a heat-resistant material such as quartz (SiO₂) or silicon carbide (SiC), and is formed in a cylindrical shape with an upper end closed and a lower end opened. A manifold 209 is disposed below the reaction tube 203 concentrically with the reaction tube 203. The manifold 209 is made of a metal material such as stainless steel (SUS), for example, into a cylindrical shape with an upper end and a lower end opened. An upper end portion of the manifold 209 engages with a lower end portion of the reaction tube 203 and is configured to support the reaction tube 203. An O-ring 220a serving as a seal member is provided between the manifold 209 and the reaction tube 203. The reaction tube 203 is vertically installed similarly to the heater 207. A processing container (reaction container) mainly includes the reaction tube 203 and the manifold 209. A processing chamber 201 is formed in a cylinder hollow portion of the processing container. The processing chamber 201 is configured to be capable of accommodating a wafer 200 serving as a substrate. The wafer 200 is processed in the processing chamber 201.

In the processing chamber 201, nozzles 249a to 249c serving as first to third suppliers, respectively, are provided so as to penetrate a side wall of the manifold 209. The nozzles 249a to 249c are also referred to as first to third nozzles, respectively. The nozzles 249a to 249c are each made of, for example, a heat-resistant material such as quartz or SiC. Gas supply pipes 232a to 232c are connected to the nozzles 249a to 249c, respectively. The nozzles 249a to 249c are nozzles different from one another, and the nozzles 249a and 249c are provided adjacent to the nozzle 249b.

The gas supply pipes 232a to 232c are provided with mass flow controllers (MFCs) 241a to 241c serving as flow rate controllers (flow rate controllers), and valves 243a to 243c serving as opening/closing valves, respectively, in this order from an upstream side of a gas flow. A gas supply pipe 232d is connected to a downstream side of the valve 243a of the gas supply pipe 232a. A gas supply pipe 232e is connected to a downstream side of the valve 243b of the gas supply pipe 232b. A gas supply pipe 232f is connected to a downstream side of the valve 243c of the gas supply pipe 232c. In the gas supply pipes 232d to 232f, MFCs 241d to 241f and valves 243d to 243f are provided, respectively, in this order from the upstream side of the gas flow. The gas supply pipes 232a to 232f are each made of a metal material, for example, such as SUS.

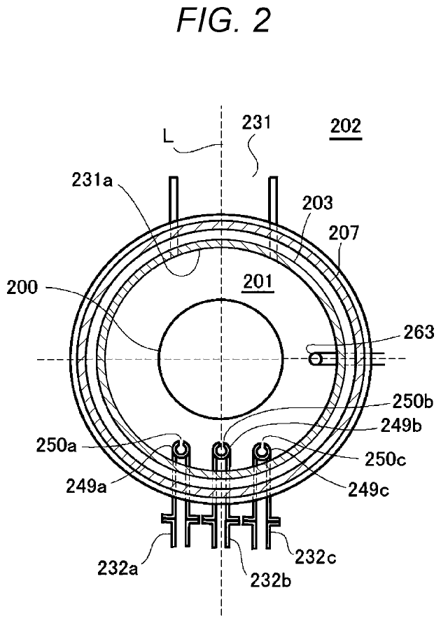

As illustrated in FIG. 2, the nozzles 249a to 249c are provided in an annular space in a plan view between an inner wall of the reaction tube 203 and the wafers 200 so as to extend upward in an arrangement direction of the wafers 200 along the inner wall of the reaction tube 203 from a lower portion toward an upper portion. That is, the nozzles 249a to 249c are provided along a wafer arrangement area, in an area horizontally surrounding the wafer arrangement area lateral to the wafer arrangement area in which the wafers 200 are arranged. In a plan view, the nozzle 249b is arranged so as to be opposed to an exhaust port 231a to be described later on a straight line across the center of the wafer 200 in the processing chamber 201. The nozzles 249a and 249c are arranged so as to interpose a straight line L passing through the nozzle 249b and the center of the exhaust port 231a from both sides along the inner wall of the reaction tube 203 (outer peripheral portion of the wafer 200). The straight line L is also a straight line passing through the nozzle 249b and the center of the wafer 200. That is, it can also be said that the nozzle 249c is provided on a side opposite to the nozzle 249a across the straight line L. The nozzles 249a and 249c are arranged in line symmetry with the straight line L as a symmetry axis. On side surfaces of the nozzles 249a to 249c, gas supply holes 250a to 250c through which a gas is supplied are provided, respectively. The gas supply holes 250a to 250c are each opened so as to be opposed to (face) the exhaust port 231a in a plan view, and can supply the gas toward the wafer 200. A plurality of gas supply holes 250a, a plurality of gas supply holes 250b, and a plurality of gas supply holes 250c are provided from the lower portion to the upper portion of the reaction tube 203.

A modifying agent is supplied from the gas supply pipe 232a into the processing chamber 201 via the MFC 241a, the valve 243a, and the nozzle 249a.

An etching agent is supplied from the gas supply pipe 232b into the processing chamber 201 via the MFC 241b, the valve 243b, and the nozzle 249b.

A removing agent is supplied from the gas supply pipe 232c into the processing chamber 201 via the MFC 241c, the valve 243c, and the nozzle 249c.

Inert gases are supplied from the gas supply pipes 232d to 232f into the processing chamber 201 through the MFCs 241d to 241f, the valves 243d to 243f, the gas supply pipes 232a to 232c, and the nozzles 249a to 249c, respectively. The inert gas acts as a purge gas, a carrier gas, a diluent gas and the like.

A modifying agent supply system (modifying agent exposure system) mainly includes the gas supply pipe 232a, the MFC 241a, and the valve 243a. An etching agent supply system (etching agent exposure system) mainly includes the gas supply pipe 232b, the MFC 241b, and the valve 243b. A removing agent supply system (removing agent exposure system) mainly includes the gas supply pipe 232c, the MFC 241c, and the valve 243c. An inert gas supply system mainly includes the gas supply pipes 232d to 232f, the MFCs 241d to 241f, and the valves 243d to 243f.

Any or all of the above-described various supply systems may be configured as an integrated supply system 248 in which the valves 243a to 243f, the MFCs 241a to 241f and the like are integrated. The integrated supply system 248 is connected to each of the gas supply pipes 232a to 232f, and is configured such that a supplying operation of various substances (various gases) into the gas supply pipes 232a to 232f, that is, an opening/closing operation of the valves 243a to 243f, a flow rate regulating operation by the MFCs 241a to 241f and the like are controlled by a controller 121 described later. The integrated supply system 248 is configured as an integral or separable integrated unit, and can be attached to and detached from the gas supply pipes 232a to 232f and the like in units of integrated units, so that maintenance, replacement, expansion and the like of the integrated supply system 248 can be performed in units of integrated units.

The exhaust port 231a from which an atmosphere inside the processing chamber 201 is discharged is provided in a lower portion of a side wall of the reaction tube 203. As illustrated in FIG. 2, the exhaust port 231a is provided at a position opposed to (facing) the nozzles 249a to 249c (gas supply holes 250a to 250c) across the wafer 200 in a plan view. The exhaust port 231a may be provided along the side wall of the reaction tube 203 from the lower portion toward the upper portion, that is, along the wafer arrangement area. An exhaust pipe 231 is connected to the exhaust port 231a. A vacuum pump 246 serving as a vacuum-exhauster is connected to the exhaust pipe 231 via a pressure sensor 245 serving as a pressure detector (pressure detector) that detects a pressure in the processing chamber 201 and an auto pressure controller (APC) valve 244 serving as a pressure regulator (pressure regulator). The APC valve 244 is configured to be capable of performing vacuum exhaust and stop the vacuum exhaust inside the processing chamber 201 by opening and closing the valve in a state in which the vacuum pump 246 is operated, and to be capable of regulating a pressure in the processing chamber 201 by regulating a degree of valve opening on the basis of pressure information detected by the pressure sensor 245 in a state in which the vacuum pump 246 is operated. An exhaust system mainly includes the exhaust pipe 231, the APC valve 244, and the pressure sensor 245. The vacuum pump 246 may be included in the exhaust system.

Below the manifold 209, a seal cap 219 is provided serving as a furnace opening lid capable of airtightly closing a lower end opening of the manifold 209. The seal cap 219 is made of, for example, a metal material such as SUS, and is formed in a disk shape. An O-ring 220b serving as a seal member that abuts the lower end of the manifold 209 is provided on an upper surface of the seal cap 219. A rotator 267 that rotates a boat 217 to be described later is arranged below the seal cap 219. A rotating shaft 255 of the rotator 267 penetrates the seal cap 219 and is connected to the boat 217. The rotator 267 is configured to rotate the boat 217, thereby rotating the wafer 200. The seal cap 219 is configured to be lifted up and down in a vertical direction by a boat elevator 115 serving as a lifter arranged outside the reaction tube 203. The boat elevator 115 is configured as a transferrer (transferrer) that lifts the seal cap 219 up and down, thereby loading/unloading (transferring) the wafer 200 into/from the processing chamber 201.

Below the manifold 209, a shutter 219s serving as a furnace opening lid capable of airtightly closing the lower end opening of the manifold 209 in a state in which the seal cap 219 is lowered and the boat 217 is unloaded from the inside of the processing chamber 201 is provided. The shutter 219s is made of, for example, a metal material such as SUS into a disk shape. An O-ring 220c serving as a seal member that abuts the lower end of the manifold 209 is provided on an upper surface of the shutter 219s. An opening/closing operation (lifting operation, rotating operation and the like) of the shutter 219s is controlled by a shutter opener/closer 115s.

The boat 217 serving as a substrate support is configured to support a plurality of, for example, 25 to 200 wafers 200 in multiple stages, that is, to arrange the wafers 200 at intervals, while the wafers 200 are aligned in the vertical direction in a horizontal posture and in a state in which the centers thereof are aligned with one another. The boat 217 is made of, for example, a heat-resistant material such as quartz and SiC. Heat insulating plates 218 each made of a heat-resistant material such as quartz or SiC, for example, are supported in multiple stages in a lower portion of the boat 217.

A temperature sensor 263 serving as a temperature detector is provided in the reaction tube 203. By regulating the degree of energization to the heater 207 on the basis of temperature information detected by the temperature sensor 263, the temperature in the processing chamber 201 has a desired temperature distribution. The temperature sensor 263 is provided along the inner wall of the reaction tube 203.

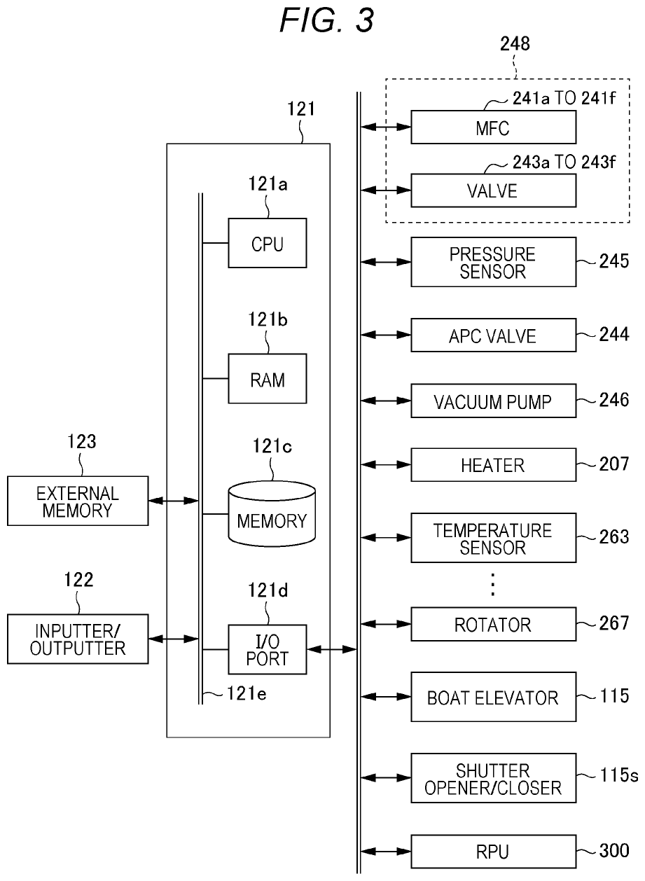

As illustrated in FIG. 3, the controller 121, which is a controller (controller), is configured as a computer including a central processing unit (CPU) 121a, a random access memory (RAM) 121b, a memory 121c, and an I/O port 121d. The RAM 121b, the memory 121c, and the I/O port 121d are configured to be capable of exchanging data with the CPU 121a via an internal bus 121e. An inputter/outputter 122 configured as, for example, a touch panel and the like is connected to the controller 121. An external memory 123 can be connected to the controller 121. The processing apparatus may be provided with one controller or a plurality of controllers. That is, control for performing a processing sequence to be described later may be performed using one controller or a plurality of controllers. A plurality of controllers may be configured as a control system in which the controllers are mutually connected by a wired or wireless communication network, and control for performing the processing sequence to be described later may be performed by the entire control system. In a case where the term controller is used in the present specification, this might include a case where a plurality of controllers is included and a case where a control system constituted by a plurality of controllers is included in addition to a case where one controller is included.

The memory 121c includes, for example, a flash memory, a hard disk drive (HDD), a solid state drive (SSD) and the like. In the memory 121c, a control program that controls an operation of the processing apparatus, a process recipe in which procedures, conditions and the like of substrate processing to be described later are described and the like are readably recorded and stored. The process recipe is a combination formed such that the controller 121 causes the processing apparatus to execute each procedure in substrate processing (etching processing and the like) to be described later to obtain a predetermined result, and functions as a program. Hereinafter, the process recipe, the control program and the like are collectively and simply referred to as a program. The process recipe is simply referred to as a recipe. In a case where the term program is used in the present specification, this might include the recipe alone, the control program alone, or both of them. The RAM 121b is configured as a memory area (work area) in which programs, data and the like read by the CPU 121a are temporarily stored.

The I/O port 121d is connected to the MFCs 241a to 241f, the valves 243a to 243f, the pressure sensor 245, the APC valve 244, the vacuum pump 246, the temperature sensor 263, the heater 207, the rotator 267, the boat elevator 115, the shutter opener/closer 115s and the like described above.

The CPU 121a is configured to be capable of reading the control program from the memory 121c and executing the control program, and reading the recipe from the memory 121c in response to an input and the like of an operation command from the inputter/outputter 122. The CPU 121a is configured to be capable of controlling, in accordance with a content of the read recipe, a flow rate regulating operation of various substances (various gases) by the MFCs 241a to 241f, an opening/closing operation of the valves 243a to 243f, an opening/closing operation of the APC valve 244 and a pressure regulating operation by the APC valve 244 based on the pressure sensor 245, start and stop of the vacuum pump 246, a temperature regulating operation of the heater 207 based on the temperature sensor 263, a rotation and rotating speed regulating operation of the boat 217 by the rotator 267, a lifting operation of the boat 217 by the boat elevator 115, an opening/closing operation of the shutter 219s by the shutter opener/closer 115s and the like.

The controller 121 can be configured by installing the above-described program recorded and stored in the external memory 123 into the computer. Examples of the external memory 123 include a magnetic disk such as an HDD, an optical disk such as a CD, a magneto-optical disk such as an MO, and a semiconductor memory such as a USB memory or an SSD. The memory 121c and the external memory 123 are configured as computer-readable recording media. Hereinafter, they are collectively and simply referred to as recording media. In a case where the term recording medium is used in the present specification, this might include a case where only the memory 121c alone is included, a case where only the external memory 123 alone is included, or a case where both of them are included. The program may be provided to the computer by using a communicator such as the Internet and a dedicated line without using the external memory 123.

### (2) Processing Step

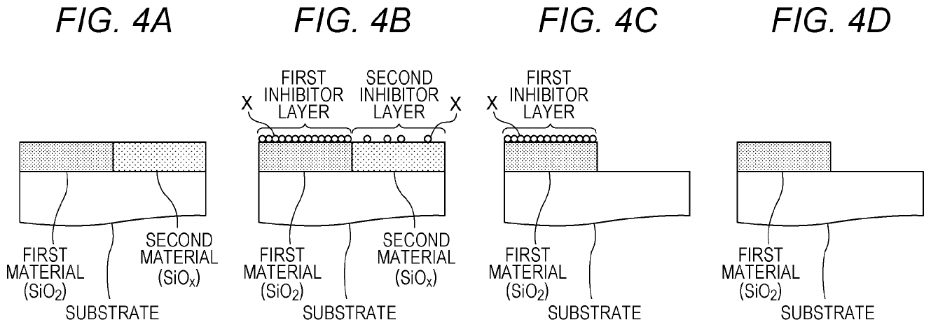

As one of steps of manufacturing (method of manufacturing) a semiconductor device using the processing apparatus described above, an example of a method of processing a substrate (processing method), that is, a processing sequence for selectively etching a second material out of first and second materials on a surface of the wafer 200 as the substrate will be described mainly with reference to FIGS. 4A to 4D. In the following description, the controller 121 controls the operation of each unit forming the processing apparatus. The processing apparatus is also referred to as a substrate processing apparatus, an etching processing apparatus, or an etching apparatus. The processing method is also referred to as a substrate processing method, an etching processing method, or an etching method.

The processing sequence in the present embodiment of the present disclosure includes:
(a) step A of modifying a surface of the first material by exposing the wafer 200, the surface of which includes the first material and the second material containing the same element as an element contained in the first material, to the modifying agent such that at least a part X of a molecular structure of a molecule contained in the modifying agent adsorbs to the surface of the first material to form a first inhibitor layer; and
(b) step B of etching the second material by exposing the wafer 200, in which the surface of the first material has been modified, to the etching agent.

The series of processing is also referred to as etching processing.

In the following example, a case where the above-described step A and step B are alternately performed a predetermined number of times (n times, n is 1 or an integer equal to or greater than 2) will be described.

In the following example, a case will be described in which (c) step C of performing at least either removal or invalidation of the first inhibitor layer remaining on the surface of the first material after the etching processing is finished is further performed. At step C, for example, the wafer 200 is exposed to the removing agent. Step C can be omitted in a case where removal or invalidation of the first inhibitor layer remaining on the surface of the first material is unnecessary after the etching processing is finished or in a case where the first inhibitor layer does not remain on the surface of the first material after the etching processing is finished.

In the present specification, the above-described processing sequence is sometimes expressed as follows for convenience. There is a case where a similar expression is used in the following description of modified example and the like.
(modifying agent→etching agent)×n
(modifying agent→etching agent)×n→removing agent

The term “wafer” used in the present specification might mean the wafer itself, or a laminate of the wafer and a predetermined layer or film formed on a surface thereof. The term “surface of the wafer” used in the present specification might mean the surface of the wafer itself or a surface of a predetermined layer and the like formed on the wafer. The expression “forming a predetermined layer on the surface of the wafer” in the present specification might mean that a predetermined layer is directly formed on the surface of the wafer itself or that a predetermined layer is formed on the layer and the like formed on the wafer. In a case where the term “substrate” is used in the present specification, this is a synonym of the term “wafer”.

The term “agent” and “substance” used in the present specification include at least either a gaseous substance or a liquid substance. The liquid substance includes a mist substance. That is, each of the modifying agent, etching agent, and removing agent may contain the gaseous substance, the liquid substance such as the mist substance, or both thereof.

### (Wafer Charge and Boat Load)

When a plurality of wafers 200 is loaded on the boat 217 (wafer charge), the shutter opener/closer 115s moves the shutter 219s, and the lower end opening of the manifold 209 is opened (shutter open). Thereafter, as illustrated in FIG. 1, the boat 217 that supports the plurality of wafers 200 is raised by the boat elevator 115 and is loaded into the processing chamber 201 (boat load). In this state, the seal cap 219 seals the lower end of the manifold 209 via the O-ring 220b. In this manner, the wafer 200 is prepared in the processing chamber 201.

As illustrated in FIG. 4A, the wafer 200 loaded on the boat 217 includes the first material and the second material containing the same element as the element contained in the first material on the surface thereof.

Each of the first material and the second material may contain a plurality of the same elements, the first material may include a film having a first composition, and the second material may include a film having a second composition different from the first composition. The first material and the second material may both contain the same plurality of elements, the first material may include a film having a stoichiometric composition, and the second material may include a film having a non-stoichiometric composition.

The density of the second material may be lower than the density of the first material. In a case where each of the first material and the second material contains the first element and the second element, the atomic concentration of the second element contained in the second material may be lower than the atomic concentration of the second element contained in the first material.

The density of an adsorption site on the surface of the second material may be lower than the density of an adsorption site on the surface of the first material. That is, the density of hydroxyl group termination (OH termination) on the surface of the second material may be lower than the density of OH termination on the surface of the first material.

The first material may include at least either a thermal oxide film or a deposition oxide film, and the second material may include at least either a native oxide film or a chemical oxide film. Here, the thermal oxide film is an oxide film formed by a thermal oxidation method. The deposition oxide film is an oxide film formed (deposited) by a method such as a chemical vapor deposition (CVD) method. The native oxide film is an oxide film formed on the surface of the wafer 200 by leaving the wafer 200 in the atmosphere. The chemical oxide film is an oxide film formed on the surface of the wafer 200 by performing predetermined cleaning processing (SC-1, SC-2 and the like) using a cleaning liquid.

FIG. 4A illustrates an example in which the first material is a thermal oxide film and the second material is a native oxide film. Specifically, a case where the first material and the second material each contain silicon (Si) as a first element and oxygen (O) as a second element, the first material includes a silicon oxide film (SiO₂ film) having a first composition (Si:O=1:2), and the second material includes a silicon oxide film (SiOₓ film) having a second composition (Si:O=1:x) different from the first composition is illustrated. Here, the first composition is a stoichiometric composition, the second composition is a non-stoichiometric composition, and x in SiOₓ is a real number smaller than 2. The density of the second material is lower than the density of the first material. The concentration of O contained in the second material is lower than the concentration of O contained in the first material. The density of the adsorption site (OH termination) on the surface of the second material is lower than the density of the adsorption site (OH termination) on the surface of the first material.

### (Pressure Regulation and Temperature Regulation)

After the boat load is finished, the inside of the processing chamber 201, that is, a space in which the wafer 200 is present is vacuum-exhausted (decompression-exhausted) by the vacuum pump 246 so as to achieve a desired pressure (vacuum degree). At that time, the pressure in the processing chamber 201 is measured by the pressure sensor 245, and the APC valve 244 is feedback-controlled on the basis of information of the measured pressure. The heater 207 heats in such a manner that temperature of the wafer 200 in the processing chamber 201 reaches desired processing temperature. At that time, on the basis of the temperature information detected by the temperature sensor 263, the degree of energization to the heater 207 is feedback-controlled in such a manner that the desired temperature distribution is obtained in the processing chamber 201. The rotator 267 starts to rotate the wafer 200. All of the exhaust in the processing chamber 201, the heating and rotation of the wafer 200 continue at least until the processing on the wafer 200 is finished.

### (Step A)

Thereafter, the wafer 200 is exposed to the modifying agent.

Specifically, the valve 243a is opened to allow the modifying agent to flow into the gas supply pipe 232a. The modifying agent a flow rate of which is regulated by the MFC 241a is supplied into the processing chamber 201 via the nozzle 249a, and discharged from the exhaust port 231a. At that time, the modifying agent is supplied from a lateral side of the wafer 200 to the wafer 200, and the wafer 200 is exposed to the modifying agent (modifying agent supply, exposure). At that time, the valves 243d to 243f may be opened to supply the inert gas into the processing chamber 201 via the nozzles 249a to 249c, respectively.

By exposing the wafer 200 to the modifying agent under processing conditions to be described later, as illustrated in FIG. 4B, at least a part X of the molecular structure of the molecule contained in the modifying agent is allowed to adsorb to the surface of the first material, and the first inhibitor layer can be selectively formed on the surface of the first material. The first inhibitor layer includes a high-density layer continuously (densely) covering the surface of the first material, that is, a continuous layer. Since the first inhibitor layer includes the continuous layer, this functions to prevent contact of the etching agent with the surface of the first material and suppress or prevent etching of the first material at step B described later. That is, the first inhibitor layer functions as a protective layer that protects the first material at step B described later. The above-described effect by the first inhibitor layer is also referred to as an inhibitor effect (reaction suppressing effect, etching suppressing effect).

In the present disclosure, the phrase “to selectively form the layer on the surface of the first material” does not mean “to form the layer only on the surface of the first material”, but means a relative relationship of degrees of layer formation processing on the surface. That is, this term means “to give priority to the formation of the layer on the surface of the first material over the formation of the layer on the surface of the second material”, and does not exclude “formation of the layer on the surface of the second material”. That is, the term “selectively” in the present disclosure means that processing on one material is preferentially performed with respect to processing on another material. The same applies to the description at step B described below, that is, the description when the wafer 200 is exposed to the etching agent.

That is, at step A, the above-described X can be allowed to adsorb not only to the surface of the first material but also to the surface of the second material, and a second inhibitor layer can be formed on the surface of the second material. FIG. 4B illustrates a case where the second inhibitor layer is formed on the surface of the second material. In this case, the density of X adsorbed to the surface of the second material is lower than the density of X adsorbed to the surface of the first material. That is, the density of the second inhibitor layer is lower than the density of the first inhibitor layer. A thickness of the second inhibitor layer is thinner than a thickness of the first inhibitor layer. The second inhibitor layer includes a low-density layer discontinuously (sparsely) covering the surface of the second material, that is, a discontinuous layer. Since the second inhibitor layer includes the discontinuous layer and partially exposes the surface of the second material, this allows the etching agent to come into contact with the surface of the second material at step B described later. The etching of the second material proceeds from a contact portion. That is, the second inhibitor layer has a low inhibitor effect and does not substantially function as a protective layer that protects the second material at step B described later.

After the first inhibitor layer is formed on the surface of the first material and the second inhibitor layer is formed on the surface of the second material, the valve 243a is closed to stop supplying the modifying agent into the processing chamber 201. Then, the inside of the processing chamber 201 is vacuum-exhausted to remove the gaseous substance and the like remaining in the processing chamber 201 from the inside of the processing chamber 201. At that time, the valves 243d to 243f are opened to supply the inert gas into the processing chamber 201 via the nozzles 249a to 249c. The inert gas supplied from the nozzles 249a to 249c acts as the purge gas, and accordingly, the inside of the processing chamber 201 is purged (purge). Processing temperature when purging at this step is preferably similar to processing temperature when supplying the modifying agent.

The processing conditions when supplying the modifying agent at step A are exemplified as follows:
processing temperature: room temperature (25° C.) to 500° C., preferably room temperature to 250° C.,
processing pressure: 1 to 2,000 Pa, preferably 10 to 1,000 Pa,
modifying agent supply flow rate: 0.001 to 10 slm, preferably 0.1 to 0.5 slm,
modifying agent supply time: 1 to 3,600 seconds, preferably 5 to 300 seconds, and
inert gas supply flow rate (per gas supply pipe): 0 to 20 slm.

In the present specification, an expression of a numerical range such as “25 to 500° C.” means that a lower limit value and an upper limit value are included in the range. Therefore, for example, “25 to 500° C.” means “equal to or higher than 25° C. and equal to or lower than 500° C.”. The same applies to other numerical ranges. In the present specification, the processing temperature means the temperature of the wafer 200 or the temperature in the processing chamber 201, and the processing pressure means the pressure in the processing chamber 201. The processing time means a time in which the processing is continued. In a case where 0 slm is included in the supply flow rate, 0 slm means a case where the substance (gas) is not supplied. The same applies to the following description.

As the modifying agent, a substance containing at least either a hydrocarbon group or an amino group can be used.

For example, as the modifying agent, bis(dipropylamino)dimethylsilane([(C₃H₇)₂N]₂Si(CH₃)₂), bis(dipropylamino)diethylsilane ([(C₃H₇)₂N]₂Si(C₂H₅)₂), bis(dimethylamino)dimethylsilane ([(CH₃)₂N]₂Si(CH₃)₂), bis(diethylamino)diethylsilane ([(C₂H₅)₂N]₂Si(C₂H₅)₂), bis(dimethylamino)diethylsilane([(CH₃)₂N]₂Si(C₂H₅)₂), bis(diethylamino)dimethylsilane ([(C₂H₅)₂N]₂Si(CH₃)₂), bis(dimethylamino)silane ([(CH₃)₂N]₂SiH₂), bis (diethylamino)silane ([(C₂H₅)₂N]₂SiH₂), bis(dimethylaminodimethylsilyl)ethane ([(CH₃)₂N(CH₃)₂Si]₂C₂H₆), bis(dipropylamino)silane ([(C₃H₇)₂N]₂SiH₂), bis(dibutylamino)silane ([(C₄H₉)₂N]₂SiH₂), (dimethylsilyl)diamine ((CH₃)₂Si(NH₂)₂), (diethylsilyl)diamine ((C₂H₅)₂Si(NH₂)₂), (dipropylsilyl)diamine ((C₃H₇)₂Si(NH₂)₂), bis(dimethylaminodimethylsilyl)methane ([(CH₃)₂N(CH₃)₂Si]₂CH₂), bis(dimethylamino)tetramethyldisilane ([(CH₃)₂N]₂(CH₃)₄Si₂) and the like can be used.

For example, as the modifying agent, (dipropylamino)trimethylsilane ((C₃H₇)₂NSi(CH₃)₃), (dibutylamino)trimethylsilane ((C₄H₉)₂NSi(CH₃)₃), (dimethylamino)trimethylsilane ((CH₃)₂NSi(CH₃)₃), (diethylamino)triethylsilane ((C₂H₅)₂NSi(C₂H₅)₃), (dimethylamino)triethylsilane ((CH₃)₂NSi(C₂H₅)₃), (diethylamino)trimethylsilane ((C₂H₅)₂NSi(CH₃)₃), (trimethylsilyl)amine ((CH₃)₃SiNH₂), (triethylsilyl)amine ((C₂H₅)₃SiNH₂), (dimethylamino)silane ((CH₃)₂NSiH₃), (diethylamino)silane ((C₂H₅)₂NSiH₃), (dipropylamino)silane ((C₃H₇)₂NSiH₃), (dibutylamino)silane ((C₄H₉)₂NSiH₃) and the like can be used.

One or more of them may be used as the modifying agent.

As the inert gas, a nitrogen (N₂) gas, or a rare gas such as an argon (Ar) gas, a helium (He) gas, a neon (Ne) gas, or a xenon (Xe) gas can be used. One or more of them can be used as the inert gas. The same applies to each step described later.

### (Step B)

After step A is finished, the wafer 200 is exposed to the etching agent.

Specifically, the valve 243b is opened to allow the etching agent to flow into the gas supply pipe 232b. The etching agent a flow rate of which is regulated by the MFC 241b is supplied into the processing chamber 201 via the nozzle 249b and discharged from the exhaust port 231a. At that time, the etching agent is supplied from the lateral side of the wafer 200 to the wafer 200, and the wafer 200 is exposed to the etching agent (etching agent supply, exposure). At that time, the valves 243d to 243f may be opened to supply the inert gas into the processing chamber 201 via the nozzles 249a to 249c, respectively.

By exposing the wafer 200 to the etching agent under processing conditions described later, it is possible to selectively etch at least a part of the second material while suppressing etching of the first material. At this step, the selective etching of the second material is enabled because, as described above, the first inhibitor layer including the high-density continuous layer functions as the protective layer of the first material, whereas the second inhibitor layer including the low-density discontinuous layer does not substantially function as the protective layer of the second material. The etching of the second material proceeds, for example, with a gap between X contained in the second inhibitor layer as a starting point. In order to progress this selective etching, it is preferable to perform step B under conditions that at least either removal or invalidation of the first inhibitor layer is suppressed. Even under such conditions, the second inhibitor layer is removed from the surface of the second material together with the surface of the second material (together with the surface of the second material) along with etching of the second material as a base.

After selectively etching the second material, the valve 243b is closed, and the supply of the etching agent into the processing chamber 201 is stopped. By the processing procedures and processing conditions similar to those in the purge at step A, the gaseous substance and the like remaining in the processing chamber 201 are removed from the inside of the processing chamber 201 (purge). The processing temperature when performing the purge at this step is preferably similar to the processing temperature when supplying the etching agent.

The processing conditions when supplying the etching agent at step B are exemplified as follows:
processing temperature: room temperature (25° C.) to 300° C., preferably room temperature to 100° C.,
processing pressure: 5 to 1,333 Pa, preferably 5 to 500 Pa,
etching agent supply flow rate: 0.001 to 2 slm, preferably 0.001 to 0.5 slm,
etching agent supply time: 1 to 300 seconds, preferably 5 to 120 seconds, and
inert gas supply flow rate (each gas supply pipe): 0 to 20 slm.

As the etching agent, a fluorine-based substance, that is, a fluorine-containing substance can be used, and for example, a fluorine (F)-containing gas can be used. As the F-containing gas, it is possible to use, for example, Cl and F-containing gas, N and F-containing gas, H and F-containing gas and the like such as chlorine trifluoride (ClF₃) gas, chlorine fluoride (ClF) gas, nitrogen trifluoride (NF₃) gas, hydrogen fluoride (HF) gas, and fluorine (F₂) gas can be used. As described above, as the etching agent, for example, Cl and F-containing substances, N and F-containing substances, H and F-containing substances, and F-containing substances can be used. That is, as the etching agent, for example, an interhalogen compound, a nitrogen halide, a hydrogen halide, a halogen simple substance or the like can be used.

As the etching agent, a gas obtained by adding an ammonia (NH₃) gas, a hydrogen (H₂) gas, water vapor (H₂O gas), an isopropyl alcohol ((CH₃)₂CHOH) gas, a methanol (CH₃OH) gas, a mixed gas thereof or the like to the above-described F-containing gas can also be used. In a case where a solid byproduct (complex or the like) is generated by adding at least any of these gases to the F-containing gas, it is preferable to appropriately add a step of sublimating the solid byproduct, for example, a heat treatment (annealing) step or the like. In this case, by performing the heat treatment step at temperature equal to or higher than the treatment temperature at the time of supplying the etching agent, preferably at temperature higher than the treatment temperature at the time of supplying the etching agent, the solid byproduct can be efficiently sublimated.

The etching agent is not limited to the above-described gaseous substance, and an aqueous solution containing a fluorine-based substance, for example, an HF aqueous solution can be used.

One or more of them can be used as the etching agent.

### [Perform Predetermined Number of Times]

By alternately performing step A and step B described above a predetermined number of times, that is, by performing the cycle including steps A and B described above a predetermined number of times (n times: n is an integer of 1 or 2 or larger), it is possible to etch the second material by a predetermined amount while suppressing etching of the first material. The cycle described above is preferably repeated a plurality of times. That is, it is preferable to make a thickness of the second material etched in one cycle thinner than a desired etching thickness (predetermined amount) in the second material, and repeat the above-described cycle a plurality of times until the etching thickness of the second material reaches a desired thickness (depth). By performing the above-described cycle a predetermined number of times, all of the second material can be etched as illustrated in FIG. 4C.

When step B is performed, a part of the first inhibitor layer may be removed or invalidated, and a part of the first material may be exposed. Even in this case, by performing step A in the next cycle, the first inhibitor layer can be formed again so as to cover an exposed portion and the like of the first material, and the first inhibitor layer can be repaired and reinforced. This makes it possible to protect the surface of the first material by the first inhibitor layer after repair and reinforcement and to suppress etching of the first material even at step B performed thereafter. That is, in the second cycle (second cycle) and subsequent cycles, at each step, the reaction similar to that in the first cycle (first cycle) can be generated, and the reaction similar to that in the first cycle can be allowed to proceed.

### (Step C)

After the etching processing is finished, the wafer 200 is exposed to the removing agent.

Specifically, the valve 243c is opened to allow the removing agent to flow into the gas supply pipe 232c. The removing agent a flow rate of which is regulated by the MFC 241c is supplied into the processing chamber 201 via the nozzle 249c, and discharged from the exhaust port 231a. At that time, the removing agent is supplied from the lateral side of the wafer 200 to the wafer 200, and the wafer 200 is exposed to the removing agent (removing agent supply, exposure). At that time, the valves 243d to 243f may be opened to supply the inert gas into the processing chamber 201 via the nozzles 249a to 249c, respectively.

At least either removal or invalidation of the first inhibitor layer remaining on the surface of the first material can be performed by exposing the wafer 200 to the removing agent under processing conditions described later. FIG. 4D illustrates a case where the first inhibitor layer remaining on the surface of the first material is removed. By removing the first inhibitor layer from the surface of the first material, when a film is subsequently formed on the surface of the first material, in-plane film thickness uniformity of the film, interface characteristics with the base, and surface roughness can be improved. The surface roughness means a difference in height of the surface of the film in a wafer plane or any target plane, and the smaller the value, the smoother the surface. In the present specification, when the surface roughness is improved (becomes excellent), this means that the difference in height of the surface of the film is reduced and the smoothness is improved (becomes excellent).

The processing conditions when supplying the removing agent at step C are exemplified as follows:
processing temperature: 200 to 1,000°C, preferably 400 to 700° C.,
processing pressure: 1 to 120,000 Pa,
processing time: 1 to 18,000 seconds,
removing agent supply flow rate: 0 to 50 slm, and

RF power: 0 to 10,000 W. The RF power is power applied to generate plasma in a case of performing plasma processing using the removing agent. The removing agent supply flow rate of 0 slm means a case where the removing agent is not supplied. That is, at least either removal or invalidation of the first inhibitor layer remaining on the surface of the first material can be performed without supplying the removing agent, for example, by thermal energy by heating.

As the removing agent, for example, oxygen (O)-containing gases such as an oxygen (O₂) gas, an ozone (O₃) gas, water vapor (H₂O gas), a hydrogen peroxide (H₂O₂) gas, hydrogen (H₂) gas +O₂ gas, H₂ gas +O₃ gas, deuterium (D₂) gas +O₂ gas, D₂ gas +O₃ gas, a nitrous oxide (N₂O) gas, a nitric monoxide (NO) gas, a nitrogen dioxide (NO₂) gas, a carbon dioxide (CO₂) gas, and carbon monoxide (CO) gas; nitrogen (N)-containing and hydrogen (H)-containing gases such as a NH₃ gas, a diazene (N₂H₂) gas, and a hydrazine (N₂H₄) gas; reducing gases such as a H₂ gas and a D₂ gas; inert gases such as a He gas, an Ar gas, and N₂ gas, and a mixed gas thereof can be used.

In the present specification, the description of two gases such as “H₂ gas+O₂ gas” means a mixed gas of H₂ gas and O₂ gas. In a case of supplying the mixed gas, the two gases may be mixed (premixed) in the supply pipe and then supplied into the processing chamber 201, or the two gases may be separately supplied into the processing chamber 201 from different supply pipes and mixed (post-mixed) in the processing chamber 201.

As the removing agent, these gases may be excited into a plasma state and supplied, or these gases may be excited by heat and supplied. One or more of them can be used as the removing agent. In a case where the O-containing gas is used as the removing agent at step C, the surface of the wafer 200 (the base of the second material) exposed by the removal of the second material may be oxidized. In this case, the oxide film newly formed on the surface of the wafer 200 is an oxide film having higher uniformity and better quality than those of the native oxide film included in the second material.

### (After-Purge and Atmospheric Pressure Restoration)

After step C is finished, the inert gas as the purge gas is supplied from each of the nozzles 249a to 249c into the processing chamber 201 and is discharged from the exhaust port 231a. Therefore, the inside of the processing chamber 201 is purged, and a gas, a reaction by-product and the like remaining in the processing chamber 201 are removed from the inside of the processing chamber 201 (after-purge). Thereafter, the atmosphere in the processing chamber 201 is replaced with the inert gas (inert gas replacement), so that the pressure in the processing chamber 201 is restored to a normal pressure (atmospheric pressure restoration).

### (Boat Unload and Wafer Discharge)

Thereafter, the boat elevator 115 lowers the seal cap 219, and the lower end of the manifold 209 is opened. Then, the processed wafer 200 is unloaded from the lower end of the manifold 209 to the outside of the reaction tube 203 in a state of being supported by the boat 217 (boat unload). After the boat unload, the shutter 219s is moved, and the lower end opening of the manifold 209 is sealed with the shutter 219s via the O-ring 220c (shutter close). After being unloaded to the outside of the reaction tube 203, the processed wafer 200 is taken out from the boat 217 (wafer discharge).

Steps A to C are preferably performed in the same processing chamber (in-situ). When a series of processing is performed in-situ, the wafer 200 is not exposed to the atmosphere in the middle, and the processing can be consistently performed while the wafer 200 is placed under vacuum, and stable processing can be performed.

### (3) Effects by Present Embodiment

According to the present embodiment, one or a plurality of effects described below can be obtained.

(a) By performing above-described steps A and B, selective etching on the surface of the substrate can be performed with high accuracy. That is, it is possible to selectively etch another part (second material) while maintaining a part (first material) of the material containing the same constituent element on the surface of the substrate without etching. For example, in a case where a thermal oxide film and/or a deposition oxide film (SiO₂ film), which is an oxide film containing Si and O, and a native oxide film and/or a chemical oxide film (SiOₓ film, 0<x<2) are exposed on the surface of the substrate, it is possible to selectively etch the SiOₓ film while suppressing etching of the surface of the SiO₂ film. As a result, it is possible to selectively remove an etching target portion, which is a part of the material containing the same constituent element, with high accuracy, and it is possible to greatly improve the processing accuracy of the film.

(b) In a case where each of the first material and the second material contains the same plurality of elements, the first material includes a film having a first composition, and the second material includes a film having a second composition different from the first composition, X can be easily adsorbed to the surface of the first material, and the second material can be more easily etched than the first material. This makes it possible to effectively perform the selective formation of the first inhibitor layer on the surface of the first material and the selective etching of the second material.

(c) In a case where each of the first material and the second material contains the same plurality of elements, the first material includes a film having a stoichiometric composition, and the second material includes a film having a non-stoichiometric composition, X can be more easily adsorbed to the surface of the first material, and the second material can be more easily etched than the first material. This makes it possible to more effectively perform the selective formation of the first inhibitor layer on the surface of the first material and the selective etching of the second material. Even in a case where the density of the second material is lower than the density of the first material, a similar effect can be obtained.

(d) In a case where each of the first material and the second material contains the first element and the second element, and the atomic concentration of the second element contained in the second material is lower than the atomic concentration of the second element contained in the first material, X can be more easily adsorbed to the surface of the first material, and the second material can be more easily etched than the first material. This makes it possible to further effectively perform the selective formation of the first inhibitor layer on the surface of the first material and the selective etching of the second material. In a case where the density of the adsorption site on the surface of the second material is lower than the density of the adsorption site on the surface of the first material, and in a case where the density of hydroxyl group termination on the surface of the second material is lower than the density of hydroxyl group termination on the surface of the first material, a similar effect can be obtained.

(e) In a case where the first material includes at least either a thermal oxide film or a deposition oxide film, and the second material includes at least either a native oxide film or a chemical oxide film, the above-described action can more effectively occur. A similar effect can be obtained also in a case where the first material includes the SiO₂ film and the second material includes the SiOₓ film (x is a real number smaller than 2).

(f) At step A, when the first inhibitor layer is formed on the surface of the first material, adsorption of X to the surface of the second material can be permitted, whereby step A can be performed under conditions that X is more easily adsorbed to the surface of the first material, and the density of X adsorbed to the surface of the first material can be increased, and the first inhibitor layer can be made a denser layer. As a result, the selective etching of the second material can be effectively performed.

(g) By making the density of the second inhibitor layer lower than the density of the first inhibitor layer, the inhibitor effect by the second inhibitor layer can be reduced, and selective etching of the second material can be more effectively performed. A similar effect can be obtained also in a case where the second inhibitor layer includes a discontinuous layer and the first inhibitor layer includes a continuous layer, or in a case where the density of X adsorbed to the surface of the second material is lower than the density of X adsorbed to the surface of the first material.

(h) In a case where the modifying agent includes at least either a hydrocarbon group or an amino group, the above-described action can more effectively occur. In a case where the etching agent contains a fluorine-containing substance, for example, this contains at least either a hydrogen fluoride gas or a hydrogen fluoride aqueous solution, the similar effect can be obtained.

(i) In a case where step B is performed under conditions that at least either removal or invalidation of the first inhibitor layer is suppressed, it is possible to effectively perform the selective etching of the second material.

(j) By alternately performing steps A and B a predetermined number of times, even in a case where a part of the first inhibitor layer is removed or invalidated during etching, the first inhibitor layer can be repaired and reinforced, and the selective etching of the second material can be more effectively performed.

(k) The above-described effects can be similarly obtained even in a case where a predetermined substance is optionally selected from the various modifying agents, various etching agents, various removing agents, and various inert gases described above to be used.

### <Other Embodiment of Present Disclosure>

The embodiment of the present disclosure has been specifically described above. However, the present disclosure is not limited to the above-described embodiment, and can be variously modified without departing from the gist thereof.

For example, the first material may include a deposition oxide film, and the second material may include a chemical oxide film. For example, the first material may include a SiOₓ₁ film having a non-stoichiometric composition, and the second material may include a SiOₓ₂ film having a non-stoichiometric composition. Here, x1 and x2 are real numbers satisfying a relational expression of 2>x1>x2>0. For example, the first material may include a SiO_{1.9} film and the second material may include a SiO_{1.5} film, or the first material may include a SiO_{1.5} film and the second material may include a SiO_{1.1} film. For example, the first material may include a stoichiometric composition SiO₂ film (high density), and the second material may include a stoichiometric composition SiO₂ film (low density). For example, the first material may include a non-stoichiometric composition SiOₓ film (high density), and the second material may include a non-stoichiometric composition SiOₓ film (low density). Herein x is a real number smaller than 2. Even in these embodiments, effects similar to those in the embodiments described above can be obtained.

For example, at least either the first material and the second material may include a silicon oxycarbide film (SiOC film), silicon oxynitride film (SiON film), and a silicon oxycarbonitride film (SiOCN film) in addition to the silicon oxide film. For example, the first material may include a SiOC film (high density), and the second material may include a SiOC film (low density). For example, the first material may include a SiOC film (high O concentration), and the second material may include a SiOC film (low O concentration). For example, the first material may include a SiOC film (O-rich), and the second material may include a SiOC film (O-poor). For example, the first material may include a SiOC film (O-rich), and the second material may include a native oxide film. For example, the first material may include a SiON film (O-rich), and the second material may include a native oxide film. For example, the first material may include a SiOCN film (O-rich), and the second material may include a native oxide film. Here, O-rich means a composition in which the atomic concentration of oxygen (O) is excessive with respect to the stoichiometric composition, and O-poor means a composition in which the atomic concentration of oxygen (O) is insufficient with respect to the stoichiometric composition. Even in these embodiments, effects similar to those in the embodiments described above can be obtained.

For example, before performing step A, a step of exposing a substrate including a first material and a second material containing the same element as the element contained in the first material on the surface thereof to an oxygen (O)-containing substance may be further performed. As a result, at subsequent step A, the adsorptivity between the surface of the first material and X can be enhanced, and the inhibitor effect (reaction suppressing effect and etching suppressing effect) by the first inhibitor layer formed on the surface of the first material can be enhanced. At that time, the substrate may be exposed to the O-containing substance while the substrate is heated. As a result, the adsorptivity between the surface of the first material and X can be enhanced, and the inhibitor effect by the first inhibitor layer formed on the surface of the first material can be further enhanced. The exposure of the substrate to the O-containing substance may be performed by exposing the substrate to a gaseous O-containing substance, or may be performed by exposing the substrate to a liquid O-containing substance. The exposure of the substrate to the O-containing substance may be performed by exposing the substrate to the atmosphere.

Processing conditions when exposing the substrate to the gaseous O-containing substance before performing step A are exemplified as follows:
processing temperature: room temperature (25° C.) to 600° C., preferably 50 to 400° C.,
processing pressure: 1 to 105,000 Pa, preferably 10 to 10,000 Pa,
processing time: 1 to 10,000 seconds, preferably 5 to 3,600 seconds, and
O-containing substance supply flow rate: 0.01 to 10 slm, preferably 0.1 to 5 slm.

Processing conditions when exposing the substrate to the liquid O-containing substance before performing step A are exemplified as follows:
processing temperature: room temperature (25° C.) to 100° C., preferably 25 to 80° C., and
processing time: 1 to 10,000 seconds, preferably 5 to 3,600 seconds.

Processing conditions when exposing the substrate to the atmosphere before performing step A are exemplified as follows:
processing temperature: room temperature (25° C.) to 100° C., preferably 25 to 80° C., and
processing time: 10 minutes to 240 hours, preferably 10 minutes to 168 hours.

As the gaseous O-containing substance, various O-containing gases exemplified as the above-described removing agent can be used. As the liquid O-containing substance, for example, water (H₂O), pure water (deionized water: DIW), an aqueous solution containing hydrogen fluoride (diluted HF: DHF), an aqueous solution containing hydrogen peroxide (H₂O₂) (hydrogen peroxide water), a mixed solution containing ammonia water, hydrogen peroxide water, and pure water (ammonia-hydrogen peroxide mixture (APM)), a mixture thereof and the like can be used. As the mixture thereof, for example, a mixture of pure water and hydrogen peroxide water, a mixture of DHF and hydrogen peroxide water, a mixture of DHF and APM and the like can be used. One or more of them can be used as the O-containing substance. In order to further enhance the inhibitor effect by the first inhibitor layer, it is particularly preferable to use O and H-containing substances such as H₂O, H₂O₂, DIW, DHF, and APM among O-containing substances. The exposure of the substrate to the O-containing substance performed before step A may be performed in the same processing chamber (in-situ) as steps A to C, or may be performed in a different processing chamber (ex-situ).

Preferably, a recipe used in each processing is individually prepared according to processing contents and is recorded and stored in the memory 121c via an electric communication line or the external memory 123. When each processing is started, the CPU 121a preferably appropriately selects an appropriate recipe from among a plurality of recipes recorded and stored in the memory 121c according to the processing contents. Therefore, it is possible to perform the various pieces of processing on films with various film types, composition ratios, film qualities, and film thicknesses with excellent reproducibility by using the processing apparatus. It is possible to reduce a burden on an operator, and it is possible to start each piece of processing quickly while avoiding an operation error.

The recipe described above is not limited to a newly created recipe, but may be prepared by, for example, changing the existing recipe already installed in the processing apparatus. In a case of changing the recipe, the changed recipe may be installed in the processing apparatus via a telecommunication line or a recording medium in which the recipe is recorded. The existing recipe already installed in the processing apparatus may be directly changed by operating the inputter/outputter 122 included in the existing processing apparatus.

In the embodiments described above, an example has been described in which the processing is performed by using a batch-type processing apparatus that processes a plurality of substrates at a time. The present disclosure is not limited to the embodiments described above, and can be applied to a case of performing the processing by using a single wafer type processing apparatus that processes one or a plurality of substrates at a time, for example. In the embodiments described above, an example of performing the processing using the processing apparatus including a hot wall type processing furnace has been described. The present disclosure is not limited to the embodiments described above, and can be applied to a case of performing the processing by using the processing apparatus including a cold wall type processing furnace.

In the embodiments described above, an example has been described in which the above-described processing sequence is performed in the same processing chamber of the same processing apparatus (in-situ). The present disclosure is not limited to the embodiments described above, and for example, any step and any other step of the above-described processing sequence may be performed in different processing chambers of different processing apparatuses (ex-situ), or may be performed in different processing chambers of the same processing apparatus.

Even in cases where such processing apparatuses are used, each piece of processing can be performed in accordance with processing procedures and processing conditions similar to those in the above-described embodiment and modified examples, so that effects similar to those in the above-described embodiments and modified examples can be obtained.

The above-described embodiments and modified examples can be used in combination as appropriate. Processing procedures and processing conditions at that time can be similar to, for example, the processing procedures and processing conditions in the embodiments and modified examples described above.

According to the present disclosure, selective etching can be performed with high accuracy.

What is claimed is:

1. A processing method comprising:
(a) modifying a surface of a first material by exposing a substrate, the surface of which includes the first material and a second material containing the same element as an element contained in the first material, to the modifying agent such that at least a part X of a molecular structure of a molecule contained in a modifying agent adsorbs to the surface of the first material to form a first inhibitor layer; and
(b) etching the second material by exposing the substrate, in which the surface of the first material has been modified, to an etching agent.

2. The processing method according to claim 1, wherein
each of the first material and the second material contains a plurality of the same elements, the first material includes a film having a first composition, and the second material includes a film having a second composition different from the first composition.

3. The processing method according to claim 1, wherein
each of the first material and the second material contains a plurality of the same elements, the first material includes a film having a stoichiometric composition, and the second material includes a film having a non-stoichiometric composition.

4. The processing method according to claim 1, wherein a density of the second material is lower than a density of the first material.

5. The processing method according to claim 1, wherein
each of the first material and the second material contains a first element and a second element, and an atomic concentration of the second element contained in the second material is lower than an atomic concentration of the second element contained in the first material.

6. The processing method according to claim 1, wherein a density of an adsorption site on a surface of the second material is lower than a density of an adsorption site on the surface of the first material.

7. The processing method according to claim 1, wherein a density of hydroxyl group termination on a surface of the second material is lower than a density of hydroxyl group termination on the surface of the first material.

8. The processing method according to claim 1, wherein
the first material includes a thermal oxide film, and the second material includes at least one selected from the group of a native oxide film and a chemical oxide film.

9. The processing method according to claim 1, wherein
the first material includes a deposition oxide film, and the second material includes at least one selected from the group of a native oxide film and a chemical oxide film.

10. The processing method according to claim 1, wherein the first material includes a SiO₂ film, and the second material includes a SiOₓ film (x is a real number smaller than 2).

11. The processing method according to claim 1, wherein
in (a), the X is adsorbed to a surface of the second material to form a second inhibitor layer.

12. The processing method according to claim 11, wherein a density of the second inhibitor layer is lower than a density of the first inhibitor layer.

13. The processing method according to claim 11, wherein
the second inhibitor layer includes a discontinuous layer, and the first inhibitor layer includes a continuous layer.

14. The processing method according to claim 11, wherein
a density of the X adsorbed to the surface of the second material is lower than a density of the X adsorbed to the surface of the first material.

15. The processing method according to claim 1, wherein the modifying agent contains at least one selected from the group of a hydrocarbon group and an amino group.

16. The processing method according to claim 1, wherein the etching agent includes a fluorine-containing substance.

17. The processing method according to claim 1, wherein
the etching agent includes at least one selected from the group of a hydrogen fluoride gas and a hydrogen fluoride aqueous solution.

18. The processing method according to claim 1, wherein (b) is performed under a condition that at least one selected from the group of removal and invalidation of the first inhibitor layer is suppressed.

19. The processing method according to claim 1, further comprising:
exposing the substrate to an oxygen-containing substance before performing (a).

20. The processing method according to claim 1, wherein (a) and (b) are alternately performed a predetermined number of times.

21. A method of manufacturing a semiconductor device, comprising the method according to claim 1.

22. A processing apparatus comprising:
a modifying agent exposure system that exposes a substrate to a modifying agent;
an etching agent exposure system that exposes the substrate to an etching agent; and
a controller configured to be capable of controlling the modifying agent exposure system and the etching agent exposure system to perform
(a) modifying a surface of a first material by exposing the substrate, the surface of which includes the first material and a second material containing the same element as an element contained in the first material, to the modifying agent such that at least a part X of a molecular structure of a molecule contained in a modifying agent adsorbs to the surface of the first material to form a first inhibitor layer; and
(b) etching the second material by exposing the substrate, in which the surface of the first material has been modified, to the etching agent.

23. A non-transitory computer-readable recording medium storing a program that causes, by a computer, a processing apparatus to perform:
(a) modifying a surface of a first material by exposing a substrate, the surface of which includes the first material and a second material containing the same element as an element contained in the first material, to the modifying agent such that at least a part X of a molecular structure of a molecule contained in a modifying agent adsorbs to the surface of the first material to form a first inhibitor layer ; and
(b) etching the second material by exposing the substrate, in which the surface of the first material has been modified, to an etching agent.
